(19) United States
(12) Patent Application Publication
(10) Pub. No.: US 2011/0156257 A1
(43) Pub. Date: Jun. 30, 2011

(54) SEMICONDUCTOR DEVICE AND METHOD FOR MANUFACTURING THE SAME

(75) Inventor: Ki Soo CHOI, Cheongju (KR)

(73) Assignee: Hynix Semiconductor Inc., Icheon (KR)

(21) Appl. No.: 12/843,641

(22) Filed: Jul. 26, 2010

(30) Foreign Application Priority Data
Dec. 29, 2009 (KR) 10-2009-0132509

(51) Int. Cl. H01L 23/532; H01L 21/768

(52) U.S. Cl. 257/751; 438/643; 257/E21.584; 257/E23.161

(57) ABSTRACT

A method for manufacturing a semiconductor device includes providing a substrate including pattern formed over the substrate and a first insulating layer formed over the pattern. A diffusion barrier layer is formed over the first insulation layer. A second insulating layer is formed over the diffusion barrier layer. The second insulating layer, the diffusion layer, and the first insulating layer are patterned to form a trench exposing the pattern. A metal layer is formed over the second insulating layer and within the trench to define a metal interconnection pattern coupling the pattern within the trench, the metal particles from the metal layer diffuse into the second insulating layer. The second insulation layer and the metal particles that have been diffused therein are removed.

### CROSS-REFERENCE TO RELATED APPLICATION

The present application claims priority to Korean patent application number 10-2009-0132509, filed on Dec. 29, 2009, which is incorporated by reference in its entirety.

### BACKGROUND OF THE INVENTION

The present invention relates to a semiconductor device and a method for manufacturing the same.

Generally, in a semiconductor device, a metal interconnection is formed in order to electrically couple elements or interconnections to each other, and a contact plug is formed in order to couple an upper metal interconnection to a lower metal interconnection.

The metal interconnection has been usually formed of aluminum (Al) or tungsten (W) having an excellent electrical conductivity. Recent studies have been conducted to use copper as a next generation metal interconnection material. Specifically, copper can solve an RC signal delay problem in a highly-integrated high-speed device because copper has a far superior electrical conductivity to that of aluminum or tungsten and also has a low resistance.

However, in the case of copper, it is difficult to perform a dry etching process for forming an interconnection. Thus a Damascene process is used to form a metal interconnection of copper. A Damascene metal interconnection process is a technology which forms a metal interconnection by forming a Damascene pattern by etching an interlayer dielectric layer, and forming a metal interconnection by filling the Damascene pattern with a copper layer. The Damascene metal interconnection process may be classified into a single-Damascene process and a dual-Damascene process.

The Damascene process has advantages in that an upper metal interconnection and a contact plug for contacting the upper metal interconnection and a lower metal interconnection in a multilayer metal interconnection can be formed at the same time, and a subsequent process is easily performed because a height difference caused by the metal interconnections can be removed.

Furthermore, in a case where a copper layer is applied as the metal interconnection material, components of the copper layer are diffused into the substrate through the interlayer dielectric layer, as opposed to a case where an aluminum layer is applied. Since the diffused components of the copper layer act as deep level impurities within the semiconductor substrate formed of silicon, a leakage current is generated. Therefore, a diffusion barrier layer must be formed in a contact interface between the copper layer and the interlayer dielectric layer. The diffusion barrier layer is generally formed in a single-layer or dual-layer structure of a Ta layer and a TaN layer through a physical vapor deposition (PVD) process.

### BRIEF SUMMARY OF THE INVENTION

In an embodiment of the present invention, a method for manufacturing a semiconductor device includes: sequentially forming a first insulation layer, a diffusion barrier layer, and a second insulation layer on a semiconductor substrate including a contact; forming a metal interconnection region by etching the second insulation layer, the diffusion barrier layer, and the first insulation layer by using a metal interconnection mask until the contact is exposed; filling the metal interconnection region with a barrier metal and a metal layer, and forming a metal interconnection by etching the metal layer and the barrier metal until the second insulation layer is exposed; and removing the second insulation layer.

The method may further include forming an interlayer dielectric layer and an etch stop layer between the semiconductor substrate and the first insulation layer.

The method may further include forming a capping nitride layer on a resulting structure including the metal interconnection.

The metal layer may include copper (Cu).

The removing of the second insulation layer may include a wet etching process.

The second insulation layer may be an insulation layer into which copper particles or copper ions are penetrated.

The forming of the metal interconnection by etching the metal layer and the barrier metal may include a chemical mechanical polishing (CMP) process.

The diffusion barrier layer may be formed of nitride.

In another embodiment of the present invention, a semiconductor device includes: a semiconductor substrate including a contact; an insulation layer and a diffusion barrier layer disposed on the semiconductor substrate; and a metal interconnection disposed in a region where the diffusion barrier layer and the insulation layer are etched, wherein the metal interconnection further protrudes than the diffusion barrier layer.

The semiconductor device may include an interlayer dielectric layer and an etch stop layer disposed between the semiconductor substrate and the insulation layer.

The semiconductor may further include a capping nitride layer surrounding the metal interconnection.

The metal interconnection may include copper (Cu).

The diffusion barrier layer may include nitride.

### BRIEF DESCRIPTION OF THE DRAWINGS

FIGS. 1A to 1C are cross-sectional views illustrating a semiconductor device according to an embodiment of the present invention and a method for manufacturing the same.

### DESCRIPTION OF EMBODIMENTS

Description will now be made in detail with reference to the embodiments of the present invention and accompanying drawings. Wherever possible, the same reference numbers will be used throughout the drawings to refer to the same or like elements.

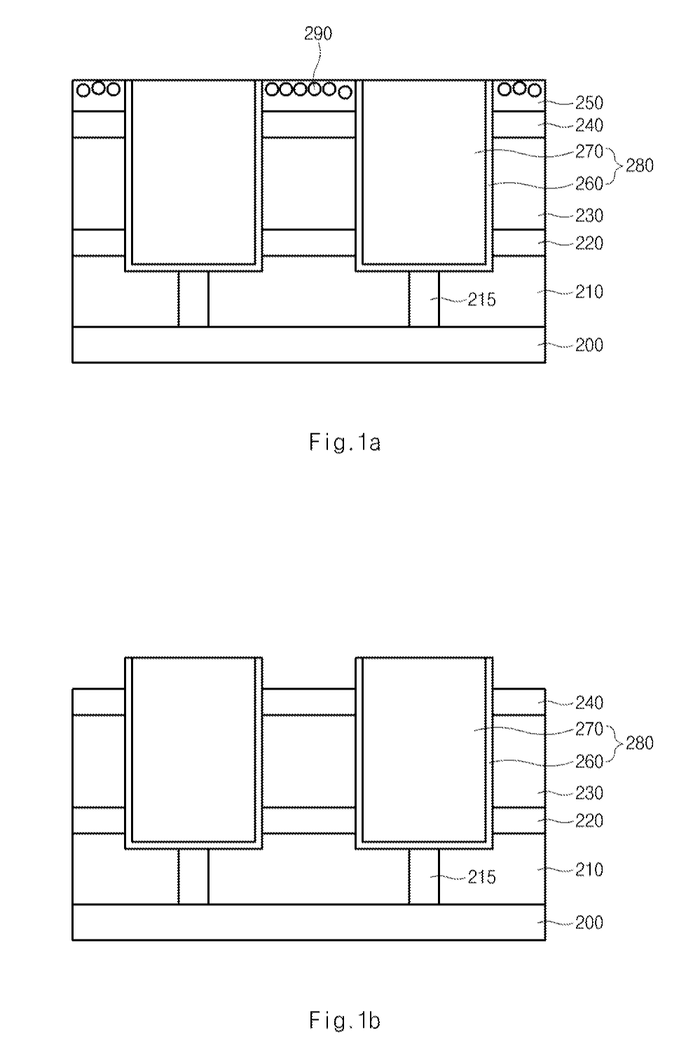

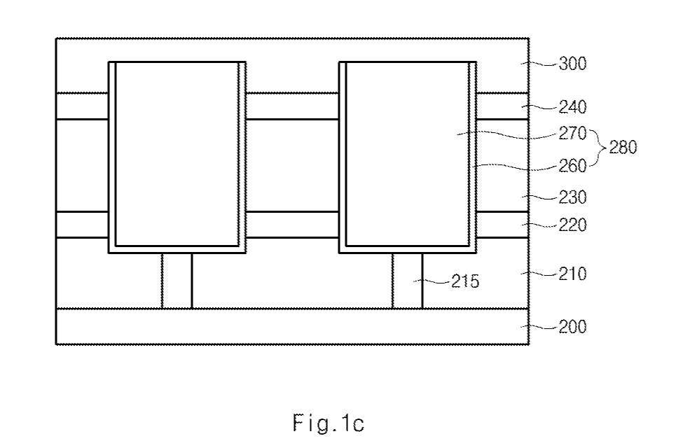

FIGS. 1A to 1C are cross-sectional views illustrating a semiconductor device and a method for manufacturing the same.

Referring to FIGS. 1A and 1B, an interlayer dielectric layer 210 is formed on a semiconductor substrate 200. A photoresist layer is formed on a resulting structure including the interlayer dielectric layer 210, and a contact 215 is formed by etching the interlayer dielectric layer 210 by an exposure process and development process using a contact mask until the semiconductor substrate 200 is exposed.

An etch stop layer 220 is formed on the interlayer dielectric layer 210 including the contact 215. During a process of forming a metal interconnection region, the etch stop layer 220 serves to prevent overetching onto an insulation layer. The etch stop layer 220 may be formed of nitride.

A first insulation layer 230, a diffusion barrier layer 240, and a second insulation layer 250 are sequentially formed on a resulting structure including the etch stop layer 220. The diffusion barrier layer 240 prevents particles or ions of a copper layer, which are generated during a subsequent process, from being diffused under the diffusion barrier layer 240. The diffusion barrier layer 240 also serves as an etch stop layer which prevents overetching by using an etching selectivity difference between the second insulation layer 250 and the diffusion barrier layer 240. Therefore, the diffusion barrier layer 240 may be formed of nitride having an etching selectivity different from the second insulation layer 250.

A photoresist layer is formed on the second insulation layer 250, and a metal interconnection region (not shown) is formed by etching the second insulation layer 250, the diffusion barrier layer 240, the first insulation layer 230, and the etch stop layer 220 by an exposure process and development process using a metal interconnection mask until the first insulation layer 210 is exposed.

A barrier metal 260 and a copper layer 270 are deposited in the metal interconnection region, and a copper interconnection layer 280 is formed by performing a chemical mechanical polishing (CMP) process on the copper layer 270 and the barrier metal 260 until the second insulation layer 250 is exposed. When the copper interconnection layer 280 is formed by performing the CMP process on the copper layer 270, particles or ions 290 of the copper layer 270 permeates and penetrates the second insulation layer 250. These particles or ions 290 degrade the characteristics of the insulation layer which can be confirmed in a time-dependent dielectric breakdown (TDDB) test.

The TDDB test is performed as follows. If a predetermined stress is applied to an electrode coupled to the insulation layer, charges are trapped in the insulation layer, and the trapped charges gradually accelerate the quality degradation of the insulation layer. The quality of the insulation layer is evaluated by measuring time it takes for breakdown to occur.

However, according to the present embodiment, the second insulation layer 250 into which the particles or ions of the copper layer 270 permeate or penetrate is removed in a subsequent process. Thus, the particles or ions present in the second insulation layer 250 are removed as well (see FIG. 2B). The second insulation layer 250 may be removed using a wet etching process. During the removal of the second insulation layer 250, an underlying layer can be protected because the diffusion barrier layer 240 and the second insulation layer 250 have a different wet etching rate from the second insulation layer 250. Therefore, only the second insulation layer 250 can be removed.

Referring to FIG. 1C, a capping nitride layer 300 is formed on a resulting structure including the copper interconnection layer 280.

During a Damascene process using copper (Cu), the insulation layer into which the copper particles or ions penetrates is selectively removed. Hence, the degradation of the insulation layer can be prevented in the TDDB test.

The above embodiments of the present invention are illustrative and not limitative. Various alternatives and equivalents are possible. The invention is not limited by the type of deposition, etching, polishing, and patterning steps described herein. Nor is the invention limited to any specific type of semiconductor device. For example, the present invention may be implemented in a dynamic random access memory (DRAM) device or nonvolatile memory device. Other additions, subtractions, or modifications are obvious in view of the present disclosure and are intended to fall within the scope of the appended claims.

What is claimed is:

1. A method for manufacturing a semiconductor device, comprising:
forming a first insulation layer, a diffusion barrier layer, and a second insulation layer over a semiconductor substrate including a contact pattern, the second insulation layer being formed over the diffusion barrier layer that is formed over the first insulating layer;
forming a metal interconnection region by etching the second insulation layer, the diffusion barrier layer, and the first insulation layer at least until the contact pattern is exposed;
filling the metal interconnection region with a barrier metal layer and a metal layer;
etching the metal layer and the barrier metal layer at least until the second insulation layer is exposed to define a metal interconnection pattern; and
removing the second insulation layer after forming the metal interconnection pattern.

2. The method according to claim 1, further comprising forming an interlayer dielectric layer and an etch stop layer between the semiconductor substrate and the first insulation layer.

3. The method according to claim 1, further comprising:
forming a capping nitride layer over the metal interconnection pattern and the diffusion barrier layer after removing the second insulation layer.

4. The method according to claim 1, wherein the metal layer comprises copper (Cu).

5. The method according to claim 1, wherein the step of removing of the second insulation layer comprises performing a wet etching process.

6. The method according to claim 5, wherein the second insulation layer is an insulation layer having copper particles that are diffused from the metal layer.

7. The method according to claim 1, wherein the step of forming of the metal interconnection pattern by etching the metal layer and the barrier metal layer comprises performing a chemical mechanical polishing (CMP) process.

8. The method according to claim 1, wherein the diffusion barrier layer includes nitride.

9. A semiconductor device comprising:
a semiconductor substrate including a contact pattern;
an insulation layer and a diffusion barrier layer disposed over the semiconductor substrate and the contact pattern, the diffusion barrier layer being provided over the insulating layer; and
a metal interconnection pattern extending through the diffusion barrier layer and the insulating layer and having a lower surface electrically coupling an upper surface of the contact pattern,
wherein the metal interconnection pattern has an upper surface provided at a higher level than an upper surface of the diffusion barrier layer.

10. The semiconductor device according to claim 9, further comprising an interlayer dielectric layer and an etch stop layer disposed between the semiconductor substrate and the insulation layer.

11. The semiconductor device according to claim 9, further comprising a capping nitride layer over the metal interconnection pattern and the diffusion barrier layer.

12. The semiconductor device according to claim 9, wherein the metal interconnection pattern comprises copper (Cu).

13. The semiconductor device according to claim 9, wherein the diffusion barrier layer comprises nitride.

14. A method for manufacturing a semiconductor device, comprising:
providing a substrate including a pattern formed over the substrate and a first insulation layer formed over the pattern;
forming a diffusion barrier layer over the first insulation layer;
forming a second insulating layer over the diffusion barrier layer;
patterning the second insulation layer, the diffusion barrier layer, and the first insulation layer to form a trench exposing the pattern;
forming a metal layer over the second insulation layer and within the trench to define a metal interconnection pattern coupling the pattern within the trench, wherein metal particles from the metal layer diffuse into the second insulation layer; and
removing the second insulation layer and the metal particles that have been diffused therein.

15. The method according to claim 14, wherein an upper surface of the metal interconnection pattern is at a higher level than an upper surface of the diffusion barrier layer.

16. The method according to claim 14, further comprising forming a capping nitride layer over the metal interconnection pattern and the diffusion barrier layer.
